(19) United States
(12) Patent Application Publication
(10) Pub. No.: US 2025/0125160 A1
(43) Pub. Date: Apr. 17, 2025

(54) SUBSTRATE PROCESSING APPARATUS AND SUBSTRATE PROCESSING METHOD

(71) Applicant: Samsung Electronics Co., Ltd., Suwon-si (KR)

(72) Inventors: Taeheon KIM, Suwon-si (KR); Junho LEE, Suwon-si (KR); Younghoo KIM, Suwon-si (KR); Junho YOON, Suwon-si (KR); Jongwon LEE, Suwon-si (KR); Jiwoong JUNG, Suwon-si (KR); Jihoon JEONG, Suwon-si (KR)

(73) Assignee: Samsung Electronics Co., Ltd., Suwon-si (KR)

(21) Appl. No.: 18/908,049

(22) Filed: Oct. 7, 2024

(30) Foreign Application Priority Data
Oct. 12, 2023 (KR) 10-2023-0136226

(51) Int. Cl. H01L 21/67

(52) U.S. Cl. CPC H01L 21/67034

(57) ABSTRACT

A substrate processing apparatus includes a process chamber including a processing space, a substrate support configured to support a substrate in the process chamber, a fluid supply tube arranged in a lower portion of the process chamber, and a fluid supply device configured to supply a supercritical fluid to the processing space through the fluid supply tube, wherein the substrate support includes a plate structure, which is arranged in a central region of the substrate support, and on which the substrate is settled, a turbulence reduction body having a ring shape and joined to an outer portion of the plate structure, and a turbulence reduction wing joined to an outer portion of the turbulence reduction body and tilted at a certain angle toward the lower portion of the process chamber.

### CROSS-REFERENCE TO RELATED APPLICATION

This application is based on and claims priority under 35 U.S.C. § 119 to Korean Patent Application No. 10-2023-0136226, filed on Oct. 12, 2023, in the Korean Intellectual Property Office, the disclosure of which is incorporated by reference herein in its entirety.

### BACKGROUND

Various example embodiments of inventive concepts relate to a substrate processing apparatus and a substrate processing method, and more particularly, to a substrate processing apparatus and a substrate processing method, which use a supercritical fluid.

As semiconductor devices are required to be finer-sized (or it is beneficial for semiconductor devices to be finer-sized), extreme ultraviolet (EUV) lithography methods using EUV light having extremely short (or short) wavelengths have been proposed. When such EUV lithography is used, fine patterns may be formed by using photoresist patterns having small horizontal dimensions and high aspect ratios. To minimize (or reduce) the falling-down or collapse of fine patterns during the process of forming the fine patterns, although drying processes using supercritical fluids have been used, it is a matter of fact that improvements to be made still remain.

### SUMMARY

Various example embodiments of inventive concepts provide a substrate processing apparatus capable of improving the uniformity of substrate processing by preventing (or reducing) a leaning phenomenon of fine patterns in an edge region of a substrate.

The inventive concepts are not limited to the above aspect, and the above and other aspects of the inventive concepts will be clearly understood by those of ordinary skill in the art from the following descriptions.

Some example embodiments of inventive concepts provide a substrate processing apparatus including a process chamber including a processing space, a substrate support configured to support a substrate in the process chamber, a fluid supply tube arranged in a lower portion of the process chamber, and a fluid supply device configured to supply a supercritical fluid to the processing space through the fluid supply tube, wherein the substrate support includes a plate structure that is arranged in a central region of the substrate support, and on which the substrate is settled, a turbulence reduction body having a ring shape and joined to an outer portion of the plate structure, and a turbulence reduction wing joined to an outer portion of the turbulence reduction body and tilted at an angle toward the lower portion of the process chamber.

Some example embodiments of inventive concepts provide a substrate processing apparatus including a process chamber including a processing space, a substrate support configured to support a substrate in the process chamber, a fluid supply tube arranged in a side portion of the process chamber, and a fluid supply device configured to supply a supercritical fluid to the processing space through the fluid supply tube, wherein the substrate support includes a plate structure that is arranged in a central region of the substrate support, and on which the substrate is settled, a turbulence reduction body having a ring shape and joined to an outer portion of the plate structure, and a turbulence reduction wing joined to an outer portion of the turbulence reduction body and tilted at an angle toward an upper portion of the process chamber.

Some example embodiments of inventive concepts provide a substrate processing apparatus including a substrate support including a plate structure, on which a substrate is settled, a turbulence reduction body having a ring shape and joined to an outer portion of the plate structure, and a turbulence reduction wing joined to an outer portion of the turbulence reduction body and having an upper surface that is tilted, wherein the substrate processing apparatus is configured to dry a substrate by using a supercritical fluid, and wherein a center of turbulence generated due to an inflow of the supercritical fluid at high pressure is formed outwards apart from a edge of the substrate by using the substrate support.

### BRIEF DESCRIPTION OF THE DRAWINGS

Various example embodiments will be more clearly understood from the following detailed description taken in conjunction with the accompanying drawings in which:

FIG. 1 is a cross-sectional view illustrating a substrate processing apparatus according to an example embodiment;

FIG. 2 is an enlarged view of a region II of FIG. 1;

FIG. 3 is a diagram illustrating the shape of a substrate support according to a fluid supply direction of FIG. 1;

FIG. 4 is a configuration diagram illustrating a fluid supply device of a substrate processing apparatus according to an example embodiment;

FIGS. 5A and 5B are simulation diagrams respectively illustrating a direction of turbulence and a defective range of a substrate, according to an experimental example of the inventive concepts;

FIGS. 6A and 6B are simulation diagrams respectively illustrating a direction of turbulence and a defective range of a substrate, according to a comparative example that is different from the inventive concepts;

FIGS. 7 to 9 are diagrams each illustrating a substrate processing apparatus according to an example embodiment;

FIG. 10 is a flowchart illustrating a substrate processing method according to an example embodiment;

FIG. 11 is a graph illustrating changes in pressure in a process chamber during the processing of a substrate;

FIG. 12 is a plan view illustrating an overall configuration of a substrate processing apparatus according to an example embodiment;

FIG. 13 is a flowchart illustrating a method of forming a fine pattern by using a substrate processing apparatus according to an example embodiment; and

FIGS. 14 to 16 are cross-sectional views respectively illustrating a sequence of processes of the method of forming a fine pattern in FIG. 13.

### DETAILED DESCRIPTION

Hereinafter, various example embodiments of the inventive concepts will be described in detail with reference to the accompanying drawings.

As described herein, an element that is “on” another element may be above or beneath or adjacent (e.g., horizontally adjacent) to the other element. An element that is on another element may be directly on the other element, such that the element is in direct contact with the other element. An element that is on another clement may be indirectly on the other element, such that the element is isolated from direct contact with the other element by one or more interposing spaces and/or structures.

It will be understood that elements and/or properties thereof (e.g., structures, surfaces, directions, or the like), which may be referred to as being “perpendicular,” “parallel,” or the like with regard to other elements and/or properties thereof (e.g., structures, surfaces, directions, or the like) may be “perpendicular,” “parallel,” or the like or may be “substantially perpendicular,” “substantially parallel,” respectively, with regard to the other elements and/or properties thereof.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

When the terms “about” or “substantially” are used in this specification in connection with a numerical value, it is intended that the associated numerical value includes a manufacturing or operational tolerance (e.g., +10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

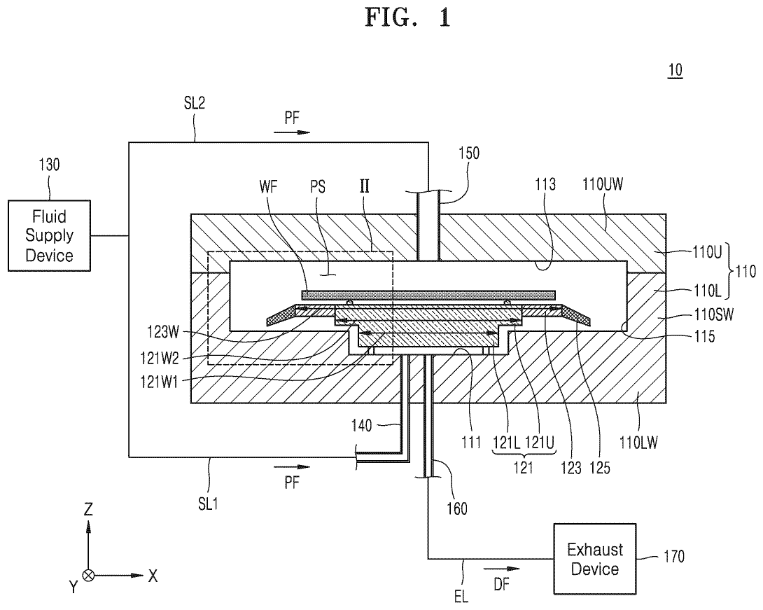

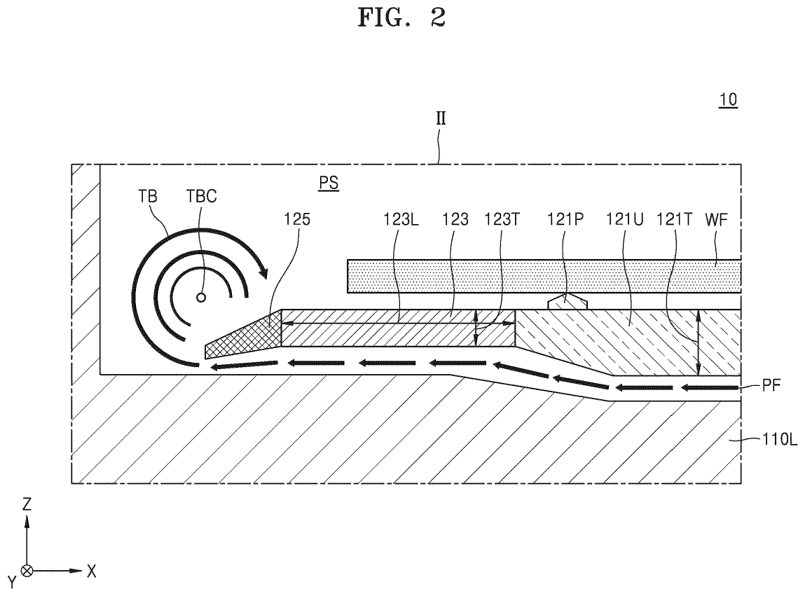

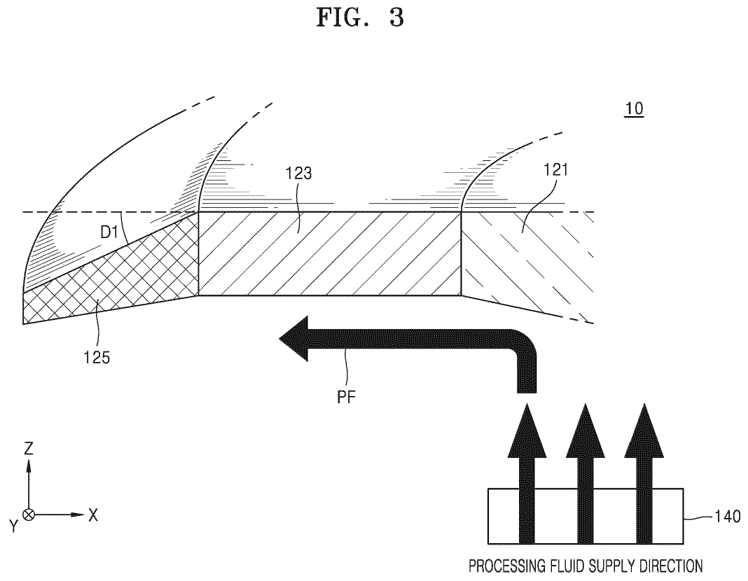

FIG. 1 is a cross-sectional view illustrating a substrate processing apparatus according to an example embodiment, FIG. 2 is an enlarged view of a region II of FIG. 1, and FIG. 3 is a diagram illustrating the shape of a substrate support according to a fluid supply direction of FIG. 1.

Referring together to FIGS. 1 to 3, a substrate processing apparatus 10 may include a process chamber 110, a substrate support 120, a fluid supply device 130, a first supply tube 140, a second supply tube 150, an exhaust tube 160, and an exhaust device 170.

The process chamber 110 may provide a processing space PS for processing a substrate WF. The process chamber 110 may seal the processing space PS from the outside of the process chamber 110 during the processing of the wafer WF. The processing space PS may be defined by a lower surface 111, an upper surface 113, and a side surface 115 of the process chamber 110. For example, the processing space PS may be defined by a lower wall 110LW including the lower surface 111 of the process chamber 110, an upper wall 110UW including the upper surface 113 of the process chamber 110, and a sidewall 110SW defining the side surface 115 of the process chamber 110.

In some example embodiments, the process chamber 110 may include a lower body 110L and an upper body 110U. The upper body 110U may be arranged on the lower body 110L. Each of the upper body 110U and the lower body 110L may include, for example, a metal material. The upper body 110U may be coupled onto the lower body 110L to cover a space provided by the lower body 110L. Each of the upper body 110U and the lower body 110L may switch between a closed position for sealing the processing space PS and an open position for opening the processing space PS to air that is outside the process chamber 110.

In the closed position of the process chamber 110, the upper body 110U and the lower body 110L may be coupled to each other to seal the processing space PS. In the open position of the process chamber 110, the upper body 110U may be separated from the lower body 110L to allow the processing space PS to be open to air that is outside the process chamber 110. The switch of the process chamber 110 between the closed position and the open position may be implemented by an elevation device (not shown) configured to move the upper body 110U in the vertical direction (Z direction) with respect to the lower body 110L.

The substrate support 120 is provided in the processing space PS and may support the substrate WF. The substrate support 120 may support the substrate WF such that the upper surface of the substrate WF faces the upper surface 113 of the process chamber 110 and the lower surface of the substrate WF faces the lower surface 111 of the process chamber 110. The upper surface of the substrate WF may be a processing target surface that is to be processed by the substrate processing apparatus 10. The substrate support 120 may be coupled to the lower wall 110LW of the process chamber 110.

In an example embodiment, the substrate support 120 may include a plate structure 121, which is arranged in a central region of the substrate support 120 and allows the substrate WF to be settled on the plate structure 121, a turbulence reduction body unit 123 (or turbulence reduction body 123) having a ring shape and joined to an outer portion of the plate structure 121, and a turbulence reduction wing unit 125 (or turbulence reduction wing 125) joined to an outer portion of the turbulence reduction body unit 123 and tilted at a first angle DI toward the lower surface 111 of the process chamber 110 (e.g.,, in the −Z direction). For example, the tilted upper surface of the turbulence reduction wing unit 125 may have a descending slope toward the lower surface 111 of the process chamber 110. In some example embodiments, the upper surface of the plate structure 121, the upper surface of the turbulence reduction body unit 123, and the uppermost surface of the turbulence reduction wing unit 125 may be at a substantially equal level.

The plate structure 121 may have a shape corresponding to the substrate WF, for example, a circular plate shape. The plate structure 121 may include, for example, a metal material or a ceramic material. The plate structure 121 may be arranged over the lower surface 111 of the process chamber 110 to cover the first supply tube 140 and the exhaust tube 160. The plate structure 121 may be located between the first supply tube 140 and the substrate WF and configured to adjust a flow direction of a processing fluid PF ejected through the first supply tube 140. The plate structure 121 may block the processing fluid PF, which is ejected through the first supply tube 140, from being directly ejected to the lower surface of the substrate WF. The plate structure 121 may guide the processing fluid PF such that the processing fluid PF ejected through the first supply tube 140 flows in the horizontal direction or the lateral direction.

The plate structure 121 may include a lower structure 121L, which has a first diameter 121W1, and an upper structure 121U, which has a second diameter 121W2 that is greater than the first diameter 121W1 of the lower structure 121L. However, this division is just for convenience of description, and the lower structure 121L and the upper structure 121U may be integrated into one body to constitute the plate structure 121. The lower structure 121L of the plate structure 121 may be supported by a support column erected on the lower surface 111 of the process chamber 110 and may be apart from the lower surface 111 of the process chamber 110 by as much as a set distance (or a desired distance).

A support pin 121P may be arranged on the upper structure 121U of the plate structure 121, and the substrate WF may be supported by the support pin 121P that is in contact with the lower surface of the substrate WF. In some example embodiments, the second diameter 121W2 of the upper structure 121U of the plate structure 121 may be less than the diameter of the substrate WF.

The turbulence reduction body unit 123 may include a structure having a ring shape and joined to the outer portion of the plate structure 121. The turbulence reduction body unit 123 may include a material which is the same as or different from that of the plate structure 121. The turbulence reduction body unit 123 may have a horizontal length 123L and a vertical thickness 123T. The vertical thickness 123T of the turbulence reduction body unit 123 may be less than a vertical thickness 121T of the upper structure 121U of the plate structure 121.

In some example embodiments, because the turbulence reduction body unit 123 has the horizontal length 123L, a third diameter 123W of the turbulence reduction body unit 123 may be greater than the second diameter 121W2 of the upper structure 121U of the plate structure 121. In addition, the third diameter 123W of the turbulence reduction body unit 123 may be equal to or greater than the diameter of the substrate WF. In some example embodiments, when the diameter of the substrate WF is about 300 mm, the third diameter 123W of the turbulence reduction body unit 123 may have a value determined from a range about 300 mm to about 335 mm.

The turbulence reduction wing unit 125 may include a material which is the same as or different from that of the turbulence reduction body unit 123. The turbulence reduction wing unit 125 may be joined to the outer portion of the turbulence reduction body unit 123 and may have an upper surface tilted at a first angle D1 toward the lower surface 111 of the process chamber 110 (e.g., in the −Z direction). In some example embodiments, the first angle DI between the upper surface of the plate structure 121 and the upper surface of the turbulence reduction wing unit 125 may be selected from a range that is greater than about 0 degrees) (°) and less than about 90°. In some example embodiments, the first angle DI between the upper surface of the plate structure 121 and the upper surface of the turbulence reduction wing unit 125 may be about 20°.

For example, the upper surface of the turbulence reduction wing unit 125 may have a decreasing level away from the turbulence reduction body unit 123. In some example embodiments, the turbulence reduction wing unit 125 may be configured to have a decreasing thickness away from the turbulence reduction body unit 123. For example, this may be similar to the shape of a wingtip of an airplane wing.

As shown in FIG. 2, the processing fluid PF ejected through the first supply tube 140 may flow such that the processing fluid PF is introduced from under the plate structure 121, passes along the turbulence reduction body unit 123 and the turbulence reduction wing unit 125, and then flows into the processing space PS. According to the flow of the processing fluid PF due to the turbulence reduction body unit 123 and the turbulence reduction wing unit 125, which constitute the substrate processing apparatus 10 of the inventive concepts, a center TBC of turbulence TB, which is generated by the inflow of the processing fluid PF at high pressure through the first supply tube 140, may be formed outwards apart from an edge of the substrate WF. This will be described below in detail.

The fluid supply device 130 may generate the processing fluid PF for processing the substrate WF and may supply the processing fluid PF, which is generated, to the processing space PS of the process chamber 110. In some example embodiments, the fluid supply device 130 may be configured to generate and supply a supercritical fluid and the substrate processing apparatus 10 may be configured to process the substrate WF by using the supercritical fluid. For example, the fluid supply device 130 may be configured to perform a drying process on the substrate WF by using the supercritical fluid.

The supercritical fluid may continuously change from a gas-like state to a liquid-like state in terms of physical properties thereof, such as density, viscosity, diffusion coefficient, and polarity, depending on (or based on) the change of pressure. The supercritical fluid is a material having a temperature of the critical temperature thereof or more and having pressure of the critical pressure thereof or more and may have diffusibility, viscosity, and surface tension like a gas and also have solubility like a liquid. In some example embodiments, when a drying process is performed on the substrate WF by using the supercritical fluid, the supercritical fluid having almost no surface tension may permeate a fine groove provided to the substrate WF and may dry a cleaning solution or a rinse solution on the substrate WF while significantly suppressing a fine pattern (or while suppressing a fine pattern) on the substrate WF from suffering from a falling-down, collapsing, or leaning phenomenon (hereinafter, collectively referred to as a leaning phenomenon).

For example, the supercritical fluid may include carbon dioxide (CO₂), water (H₂O), methane (CH₄), ethane (C₂H₆), propane (C₃H₈), ethylene (C₂H₄), propylene (C₂H₂), methanol (C₂H₃OH), ethanol (C₂H₅OH), sulfur hexafluoride (SF₆), acetone (C₃H₅O), or a combination thereof, but example embodiments are not limited thereof. In some example embodiments, the fluid supply device 130 may be configured to generate and supply a supercritical fluid including carbon dioxide (CO₂). Because carbon dioxide (CO₂) has a low critical temperature of about 31° C. and a low critical pressure of about 73 bar and is non-toxic, nonflammable, and relatively low-priced, carbon dioxide (CO₂) may be readily used for a drying process.

The fluid supply device 130 may be configured to supply the processing fluid PF to the processing space PS of the process chamber 110 through at least one of the first supply tube 140, which is arranged in the lower wall 110LW of the process chamber 110, and the second supply tube 150, which is arranged in the upper wall 110UW of the process chamber 110.

The first supply tube 140 may extend in the lower wall 110LW of the process chamber 110. The first supply tube 140 may extend downwards from the lower surface 111 of the process chamber 110. For example, the first supply tube 140 may be inserted into the lower wall 110LW of the process chamber 110.

The processing fluid PF provided by the fluid supply device 130 may be provided to the first supply tube 140 through a first supply line SL1, and an open-close valve for controlling the supply of the processing fluid PF to the first supply tube 140 may be mounted on the first supply line SL1. The processing fluid PF may be injected to the processing space PS through the first supply tube 140. In some example embodiments, the first supply tube 140 may have a circular or elliptical shape in a plan view. In some example embodiments, the first supply tube 140 may have a polygonal shape, such as a quadrangular shape, in a plan view.

The second supply tube 150 may extend in the upper wall 110UW of the process chamber 110. The second supply tube 150 may extend upwards from the upper surface 113 of the process chamber 110. For example, the second supply tube 150 may be inserted into the upper wall 110UW of the process chamber 110.

The processing fluid PF provided by the fluid supply device 130 may be provided to the second supply tube 150 through a second supply line SL2, and an open-close valve for controlling the supply of the processing fluid PF to the second supply tube 150 may be mounted on the second supply line SL2. The processing fluid PF may be injected to the processing space PS through the second supply tube 150. In some example embodiments, the second supply tube 150 may have a circular or elliptical shape in a plan view. In some example embodiments, the second supply tube 150 may have a polygonal shape, such as a quadrangular shape, in a plan view.

The exhaust device 170 may be configured to discharge a discard fluid DF in the processing space PS to the outside of the process chamber 110. The exhaust device 170 may be connected to the exhaust tube 160 arranged in the lower wall 110LW of the process chamber 110 via an exhaust line EL.

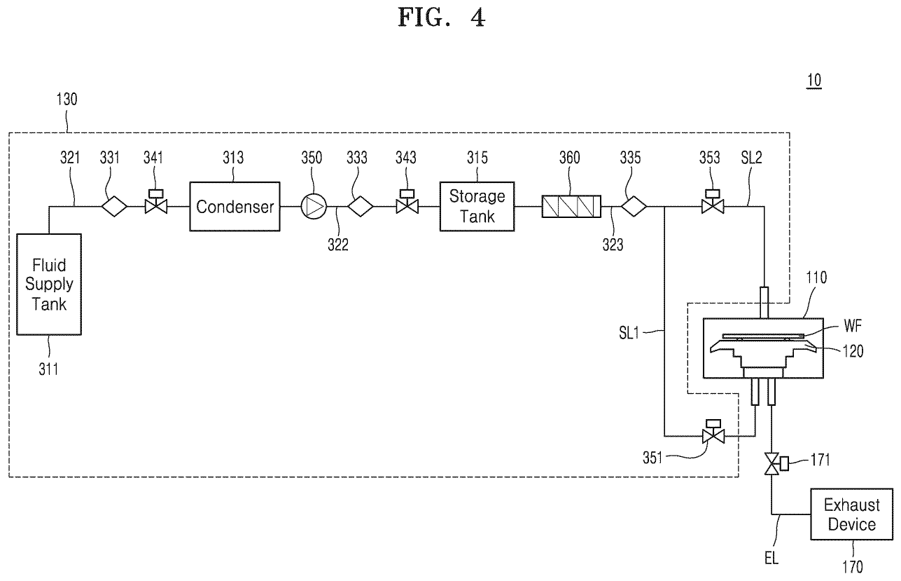

In some example embodiments, the discard fluid DF may be defined to be a fluid including various gases, chemical liquids, by-products, particles, the processing fluid PF, and the like. The discard fluid DF may be discharged from the processing space PS through the exhaust tube 160. The exhaust device 170 may include a vacuum pump, a recovery unit for recovering the discard fluid DF, an open-close valve 171 (e.g., see FIG. 4) mounted on the exhaust line EL, a flowmeter mounted on the exhaust line EL, and the like. For example, to perform an exhaustion operation by the exhaust device 170, the vacuum pump may reduce the pressure in the exhaust tube 160 and thus suck the discard fluid DF in the processing space PS into the exhaust tube 160. In some example embodiments, the exhaust device 170 may be configured to control the pressure in the processing space PS by sucking and removing the discard fluid DF in the processing space PS.

The exhaust tube 160 may extend in the lower wall 110LW of the process chamber 110. The exhaust tube 160 may extend downwards from the lower surface 111 of the process chamber 110. For example, the exhaust tube 160 may be inserted into the lower wall 110LW of the process chamber 110.

The exhaust tube 160 may be connected to the exhaust device 170 via the exhaust line EL. Through the exhaustion operation by the exhaust device 170, the discard fluid DF in the processing space PS may be sucked into the exhaust tube 160. In some example embodiments, the exhaust tube 160 may have a circular or elliptical shape in a plan view. In some example embodiments, the exhaust tube 160 may have a polygonal shape, such as a quadrangular shape, in a plan view.

Recently, as semiconductor devices are required to be finer-sized (or since it is beneficial for semiconductor devices to be finer-sized), extreme ultraviolet (EUV) lithography methods using EUV light having extremely short wavelengths (or having short wavelengths) have been proposed. Use of such EUV lithography allows fine patterns to be formed by using photoresist patterns having small horizontal dimensions and high aspect ratios. To minimize (or reduce) the falling-down or collapse of a fine pattern during the process of forming the fine pattern, a drying process using a supercritical fluid has been used. In some example embodiments, the fine pattern may include, but is not limited to, a shallow trench isolation (STI) pattern.

In general, because a supercritical fluid having almost no surface tension may permeate a fine groove provided to the substrate WF and may dry a cleaning solution or a rinse solution on the substrate WF while significantly suppressing (or while suppressing) a leaning phenomenon that may occur in a fine pattern on the substrate WF, the supercritical fluid is widely used.

However, due to the processing fluid PF supplied at high pressure through the first supply tube 140 in the initial stage of the drying process, the turbulence TB due to a pressure difference may be generated in processing space PS. Because the center TBC of the turbulence TB generated as such may be formed extremely close to the edge (or may be formed close to the edge) of the substrate WF or may overlap the edge of the substrate WF, the turbulence TB may affect the fine pattern formed on the edge of the substrate WF, and thus, there may be an issue of a leaning phenomenon of the fine pattern.

To solve such an issue, the substrate processing apparatus 10 according to the inventive concepts may allow the center TBC of the turbulence TB to be formed outwards apart from the edge of the substrate WF by using the substrate support 120, which includes the turbulence reduction wing unit 125 tilted at the first angle DI toward the lower surface 111 of the process chamber 110 (e.g., in the-Z direction), thereby efficiently preventing (or reducing) the leaning phenomenon of the fine pattern at the edge of the substrate WF and improving the uniformity of the drying process of the substrate WF.

FIG. 4 is a configuration diagram illustrating a fluid supply device of a substrate processing apparatus according to an example embodiment.

Referring together to FIGS. 1 and 4, the fluid supply device 130 may include a fluid supply tank 311, a condenser 313, a pump 350, a storage tank 315, and a heating device 360.

The fluid supply tank 311 may include a raw material. For example, the fluid supply tank 311 may store the processing fluid PF in a gaseous state. The condenser 313 may change the phase of the processing fluid PF. The condenser 313 may cool the processing fluid PF to change the processing fluid PF from a gaseous state to a liquid state. A filter 331 for filtering out impurities in the processing fluid PF and a valve 341 for adjusting the flow of the processing fluid PF may be mounted on a first fluid line 321 that connects the fluid supply tank 311 with the condenser 313.

The pump 350 may be mounted on a second fluid line 322 extending between the condenser 313 and the storage tank 315. The pump 350 may drive the processing fluid PF such that the processing fluid PF liquefied by the condenser 313 is supplied to the storage tank 315 along the second fluid line 322. A filter 333 for filtering out impurities in the processing fluid PF and a valve 343 for adjusting the flow of the processing fluid PF may be mounted on the second fluid line 322 that connects the condenser 313 with the storage tank 315.

The storage tank 315 may store the processing fluid PF and may change the phase of the processing fluid PF into a supercritical state. The storage tank 315 may heat the processing fluid PF by a heater embedded in the storage tank 315. The heater of the storage tank 315 may heat the processing fluid PF to the critical temperature of the processing fluid PF or higher. Therefore, the processing fluid PF discharged from the storage tank 315 may be in a supercritical state. The processing fluid PF discharged from the storage tank 315 may flow along a third fluid line 323 and then flow along the first supply line SL1, which extends from one end of the third fluid line 323 toward the first supply tube 140 of the process chamber 110, and/or the second supply line SL2, which extends from the one end of the third fluid line 323 toward the second supply tube 150 of the process chamber 110.

The heating device 360, which is configured to heat the processing fluid PF discharged from the storage tank 315, and a filter 335 for filtering out impurities in the processing fluid PF may be mounted on the third fluid line 323. The heating device 360 may adjust the temperature of the processing fluid PF, which is provided to the process chamber 110, by heating the processing fluid PF moving along the third fluid line 323. The heating device 360 may include an electric resistance-type heater. The heating device 360 may include an in-line heater and/or a jacket heater, which are mounted on the third fluid line 323. A valve 351 for adjusting the flow of the processing fluid PF may be mounted on the first supply line SL1, and a valve 353 for adjusting the flow of the processing fluid PF may be mounted on the second supply line SL2.

Each of the first to third fluid lines 321, 322, and 323 may include, for example, a pipe.

The fluid supply device 130 may control a first temperature of the processing fluid PF, which is provided to a lower portion of the process chamber 110 through the first supply tube 140, to be different from a second temperature of the processing fluid PF, which is provided to an upper portion of the process chamber 110 through the second supply tube 150. For example, the first temperature of the processing fluid PF and the second temperature of the processing fluid PF may be controlled by the heating device 360 and/or the heater of the storage tank 315. In some example embodiments, the first temperature of the processing fluid PF provided to the lower portion of the process chamber 110 through the first supply tube 140 may be lower than the second temperature of the processing fluid PF provided to the upper portion of the process chamber 110 through the second supply tube 150.

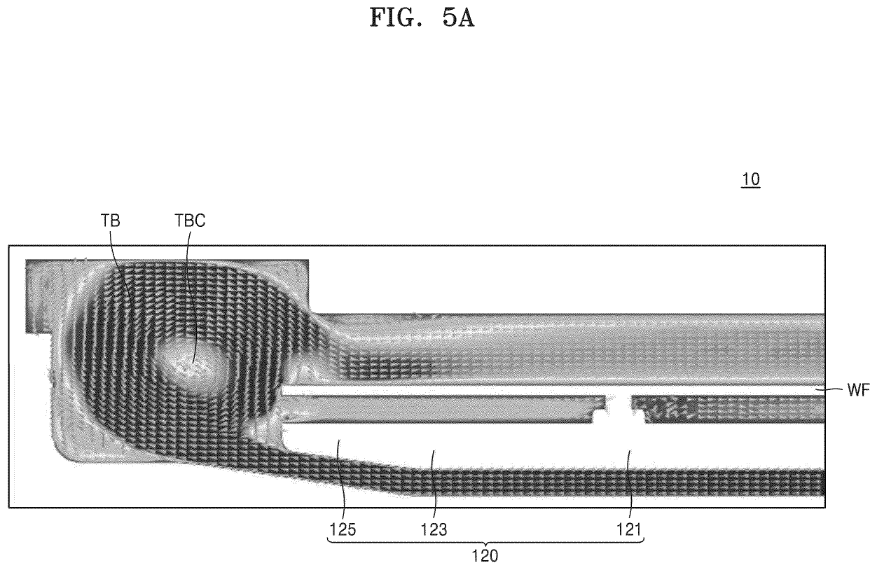

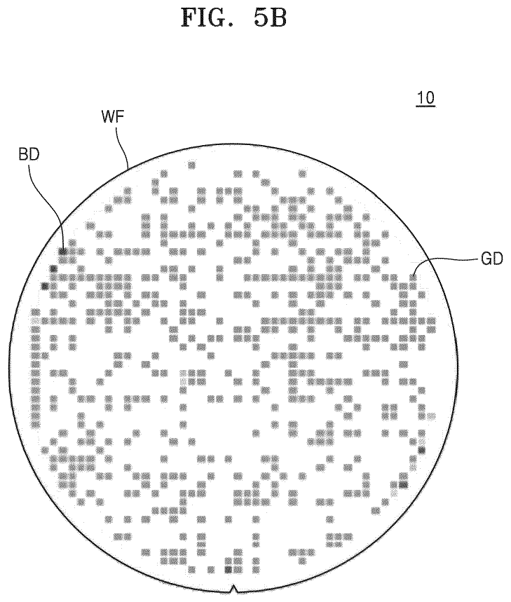

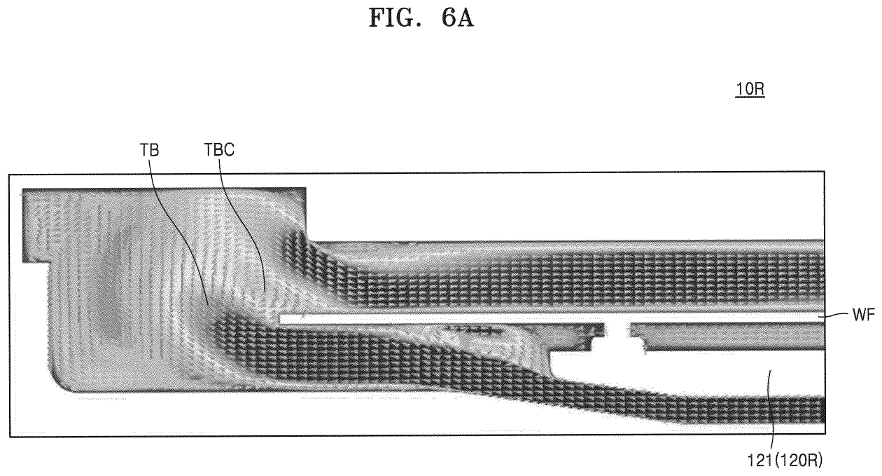

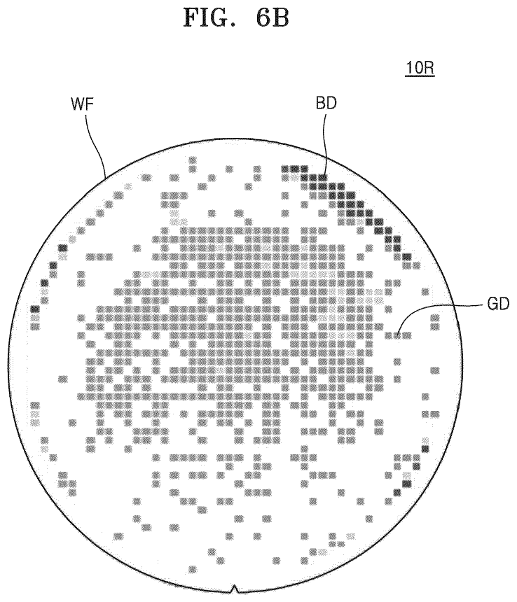

FIGS. 5A and 5B are simulation diagrams respectively illustrating a direction of turbulence and a defective range of a substrate, according to an experimental example of the inventive concepts, and FIGS. 6A and 6B are simulation diagrams respectively illustrating a direction of turbulence and a defective range of a substrate, according to a comparative example that is different from the inventive concepts.

Referring together to FIGS. 5A and 5B, in the substrate processing apparatus 10 according to the experimental example, the substrate WF is arranged on the substrate support 120.

In the substrate processing apparatus 10 according to the experimental example, the substrate support 120 may include the plate structure 121, which is arranged in the central region of the substrate support 120, the turbulence reduction body unit 123 having a ring shape and joined to the outer portion of the plate structure 121, and the turbulence reduction wing unit 125 joined to the outer portion of the turbulence reduction body unit 123.

As described above, due to a processing fluid supplied at high pressure in the initial stage of a drying process, the turbulence TB due to a pressure difference may be generated in a processing space. In the substrate processing apparatus 10 according to the experimental example, the center TBC of the turbulence TB generated as such may be formed outwards apart from the edge of the substrate WF by the turbulence reduction body unit 123 and the turbulence reduction wing unit 125, thereby efficiently preventing (or reducing) a leaning phenomenon of a fine pattern at the edge of the substrate WF.

As a result, at the edge of the substrate WF, because a bad die BD, which corresponds to a defective product due to a leaning phenomenon of a pattern, is fabricated in a relatively small number (or in a small number), a good die GD, which corresponds to a good product without a leaning phenomenon of a pattern, may be fabricated in a large number.

For example, the inventors of the inventive concepts determined from the simulation results that, in the substrate processing apparatus 10 according to the experimental example, the leaning phenomenon of the fine pattern due to the turbulence TB may be generated at a relatively low degree (or at a low degree) at the edge of the substrate WF, thereby improving the uniformity in the processing of the substrate WF and increasing the production yield of products.

Referring together to FIGS. 6A and 6B, in a substrate processing apparatus 10R according to the comparative example, the substrate WF is arranged on a substrate support 120R.

In the substrate processing apparatus 10R according to the comparative example, the substrate processing apparatus 10R may include the plate structure 121 but may not include a turbulence reduction body unit and a turbulence reduction wing unit, which are joined to the outer portion of the plate structure 121.

As described above, due to a processing fluid supplied at high pressure in the initial stage of a drying process, the turbulence TB due to a pressure difference may be generated in a processing space. Because the center TBC of the turbulence TB generated as such may be formed extremely close to the edge (or may be formed close to the edge) of the substrate WF or may overlap the edge of the substrate WF, the turbulence TB may affect a fine pattern formed at the edge of the substrate WF, and thus, there may be an issue of a leaning phenomenon of the fine pattern.

As a result, at the edge of the substrate WF, because the bad die BD, which corresponds to a defective product due to a leaning phenomenon of a pattern, is fabricated in a large number, the good die GD, which corresponds to a good product without a leaning phenomenon of a pattern, may be fabricated in a relatively small number (or in a small number).

For example, the inventors of the inventive concepts determined from the simulation results that, in the substrate processing apparatus 10R according to the comparative example, because the leaning phenomenon of the fine pattern due to the turbulence TB may be generated at a relatively high degree (or at a high degree) at the edge of the substrate WF, the uniformity in the processing of the substrate WF may deteriorate and there may be an issue of the reduction in the production yield of products.

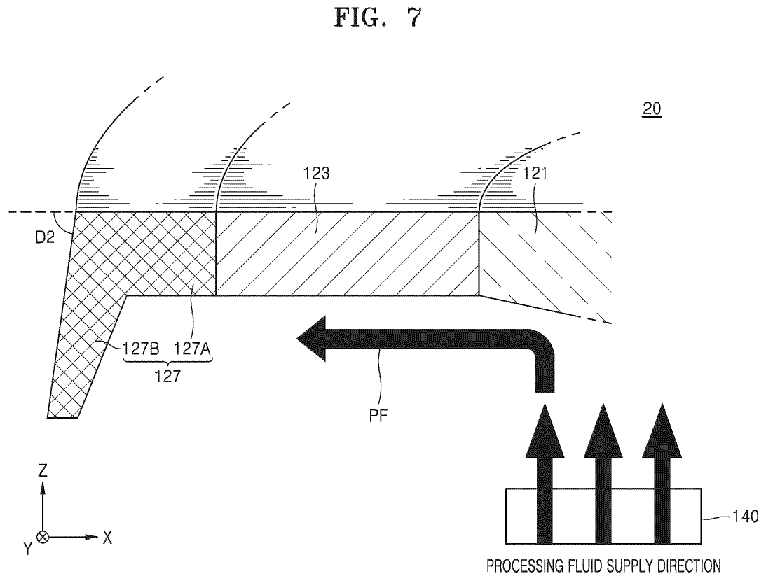

FIGS. 7 to 9 are diagrams each illustrating a substrate processing apparatus according to an example embodiment.

Most components constituting each of substrate processing apparatuses 20, 30, and 40 described below and materials respectively constituting the components are substantially the same as those described above with reference to FIGS. 1 to 3. Therefore, for convenience of description, differences from the substrate processing apparatus 10 described above are mainly described.

Referring to FIG. 7, the substrate processing apparatus 20 including a turbulence reduction wing unit 127 (or turbulence reduction wing 127) is illustrated.

The processing fluid PF ejected through the first supply tube 140 may flow such that the processing fluid PF is introduced from under the plate structure 121, passes along the turbulence reduction body unit 123 and the turbulence reduction wing unit 127, and then flows into a processing space.

In the substrate processing apparatus 20 according to an example embodiment, the turbulence reduction wing unit 127 may include a parallel portion 127A, which is joined to the outer portion of the turbulence reduction body unit 123 and is parallel to the turbulence reduction body unit 123, and a tilted portion 127B, which is tilted at a second angle D2 downwards (e.g., in the −Z direction). In some example embodiments, the second angle D2 between the upper surface of the parallel portion 127A and the upper surface of the tilted portion 127B in the turbulence reduction wing unit 127 may be selected from a range that is greater than about 0° and less than about 90°.

For example, the parallel portion 127A of the turbulence reduction wing unit 127 has an upper surface at the same level even away from the turbulence reduction body unit 123, and the tilted portion 127B of the turbulence reduction wing unit 127 has an upper surface at a decreasing level away from the turbulence reduction body unit 123. In some example embodiments, the turbulence reduction wing unit 127 may include a material which is the same as or different from that of the turbulence reduction body unit 123.

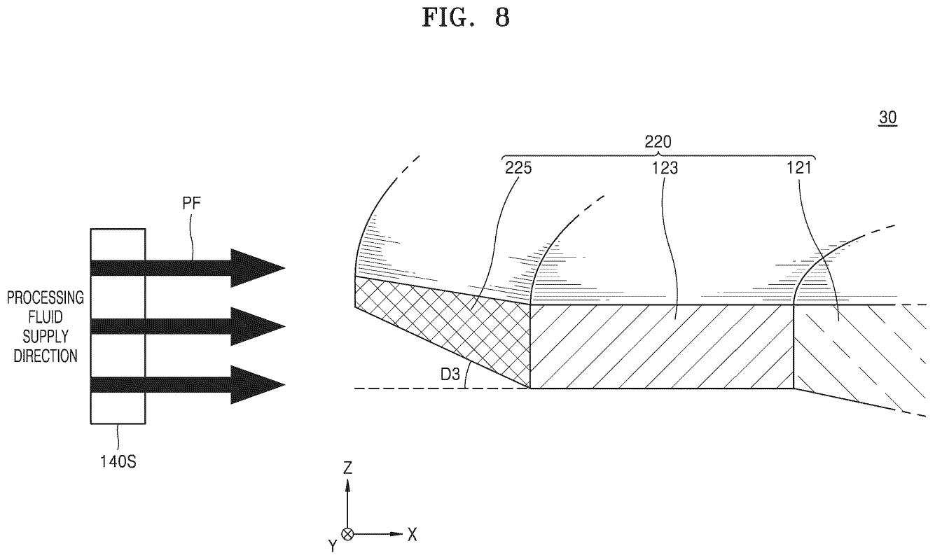

Referring to FIG. 8, the substrate processing apparatus 30 including a turbulence reduction wing unit 225 (or turbulence reduction wing 225) is illustrated.

In the substrate processing apparatus 30 according to an example embodiment, the fluid supply device 130 (e.g., see FIG. 1) may be configured to supply the processing fluid PF to a processing space of the process chamber 110 (e.g., see FIG. 1) through at least one of a first supply tube 140S, which is arranged in the sidewall 110SW (e.g., see FIG. 1) of the process chamber 110, and the second supply tube 150 (e.g., see FIG. 1), which is arranged in the upper wall 110UW (e.g., see FIG. 1) of the process chamber 110. The processing fluid PF ejected through the first supply tube 140S may flow toward the turbulence reduction wing unit 225 to be introduced into the processing space.

In the substrate processing apparatus 30 according to an example embodiment, a substrate support 220 may include the plate structure 121, which is arranged in a central region of the substrate support 220 and allows the substrate WF to be settled on the plate structure 121, the turbulence reduction body unit 123 having a ring shape and joined to the outer portion of the plate structure 121, and a turbulence reduction wing unit 225 joined to the outer portion of the turbulence reduction body unit 123 and tilted at a third angle D3 toward the upper surface 113 (e.g., see FIG. 1) of the process chamber 110 (e.g., see FIG. 1) (e.g., in the +Z direction). For example, the tilted upper surface of the turbulence reduction wing unit 225 may have an ascending slope toward the upper surface 113 (e.g., see FIG. 1) of the process chamber 110 (e.g., see FIG. 1).

In some example embodiments, the third angle D3 between the upper surface of the plate structure 121 and the upper surface of the turbulence reduction wing unit 225 may be selected from a range that is greater than about 0° and less than about 90°. In some example embodiments, the third angle D3 between the upper surface of the plate structure 121 and the upper surface of the turbulence reduction wing unit 225 may be about 20°.

For example, the turbulence reduction wing unit 225 may have an upper surface at an increasing level away from the turbulence reduction body unit 123. In some example embodiments, the turbulence reduction wing unit 225 may be configured to have a decreasing thickness away from the turbulence reduction body unit 123. For example, this may be similar to the shape of a wingtip of an airplane wing. In some example embodiments, the turbulence reduction wing unit 225 may include a material which is the same as or different from that of the turbulence reduction body unit 123.

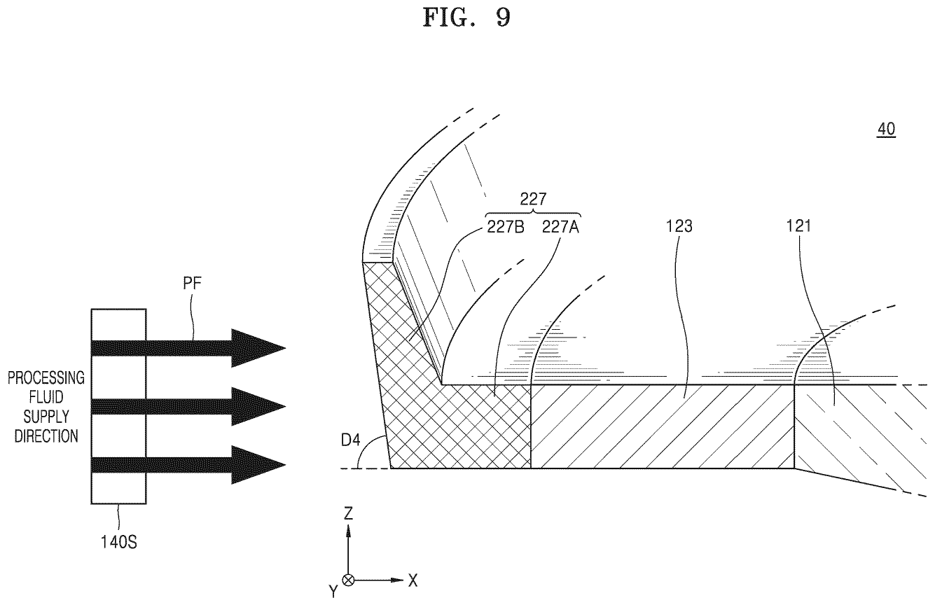

Referring to FIG. 9, the substrate processing apparatus 40 including a turbulence reduction wing unit 227 (or turbulence reduction wing 227) is illustrated.

In the substrate processing apparatus 40 according to an example embodiment, the fluid supply device 130 (e.g., see FIG. 1) may be configured to supply the processing fluid PF to a processing space of the process chamber 110 (e.g., see FIG. 1) through at least one of the first supply tube 140S, which is arranged in the sidewall 110SW (e.g., see FIG. 1) of the process chamber 110, and the second supply tube 150 (e.g., see FIG. 1), which is arranged in the upper wall 110UW (e.g., see FIG. 1) of the process chamber 110. The processing fluid PF ejected through the first supply tube 140S may flow toward the turbulence reduction wing unit 227 to be introduced into the processing space.

In the substrate processing apparatus 40 according to an example embodiment, the turbulence reduction wing unit 227 may include a parallel portion 227A, which is joined to the outer portion of the turbulence reduction body unit 123 and is parallel to the turbulence reduction body unit 123, and a tilted portion 227B, which is tilted at a fourth angle D4 upwards (e.g., in the +Z direction). In some example embodiments, the fourth angle D4 between the upper surface of the parallel portion 227A and the upper surface of the tilted portion 227B in the turbulence reduction wing unit 227 may be selected from a range that is greater than about 0° and less than about 90°.

For example, the parallel portion 227A of the turbulence reduction wing unit 227 has an upper surface at the same level even away from the turbulence reduction body unit 123, and the tilted portion 227B of the turbulence reduction wing unit 227 has an upper surface at an increasing level away from the turbulence reduction body unit 123. In some example embodiments, the turbulence reduction wing unit 227 may include a material which is the same as or different from that of the turbulence reduction body unit 123.

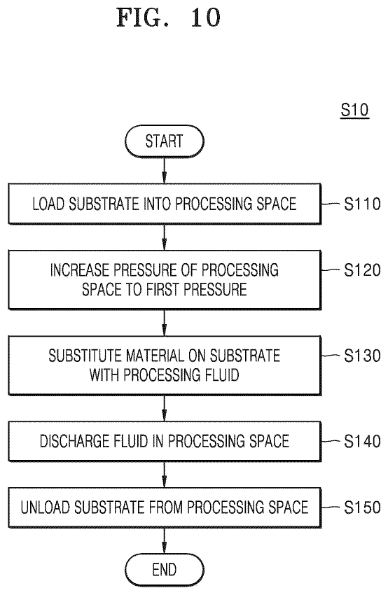

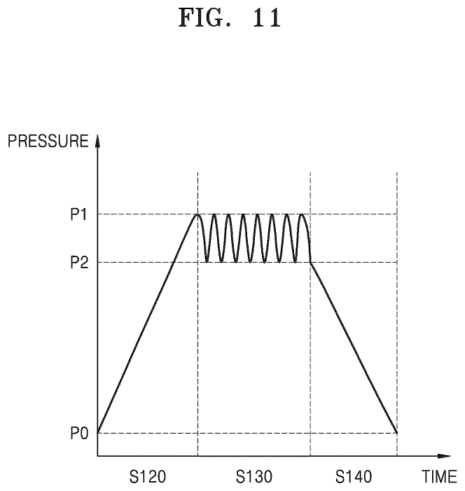

FIG. 10 is a flowchart illustrating a substrate processing method according to an example embodiment, and FIG. 11 is a graph illustrating changes in pressure in a process chamber during the processing of a substrate.

Referring together to FIGS. 1, 10, and 11, a substrate processing method S10 using one of the substrate processing apparatuses 10, 20, 30, and 40 described above is described.

In first operation S110, the substrate WF may be loaded into the processing space PS of the process chamber 110. While the substrate WF is loaded into the processing space PS, the process chamber 110 may be at an open position. The substrate WF may be settled on the substrate support 120. When the substrate WF is settled on the substrate support 120, the process chamber 110 may switch from the open position to a closed position such that the processing space PS is sealed from the outside of the process chamber 110.

After the substrate WF is loaded, a drying process is performed on the substrate WF. The drying process on the substrate WF may include second operation S120 of increasing the pressure of the processing space PS to target pressure, third operation S130 of substituting a material on the substrate WF with the processing fluid PF, and fourth operation S140 of discharging the discard fluid DF in the processing space PS.

Second operation S120 may include supplying the processing fluid PF in a supercritical state to the processing space PS to fill the processing space PS with a supercritical fluid. In some example embodiments, the fluid supply device 130 may supply the processing fluid PF in a supercritical state to the processing space PS and thus increase the pressure of the processing space PS from initial pressure P0, which is similar to atmospheric pressure, up to first pressure P1. In some example embodiments, the first pressure PI may be higher than the critical pressure of the processing fluid PF and may be about 150 bar.

In some example embodiments, second operation S120 may include a first supply operation of supplying the processing fluid PF having first temperature from under the processing space PS through the first supply tube 140 and a second supply operation of supplying the processing fluid PF having second temperature from above the processing space PS through the second supply tube 150. In the first supply operation, the first temperature of the processing fluid PF may be about 35° C. to about 70° C. In the second supply operation, the second temperature of the processing fluid PF may be higher than the first temperature of the processing fluid PF. In the second supply operation, the second temperature of the processing fluid PF may be about 70° C. to about 120° C.

In some example embodiments, the first supply operation may be performed such that the pressure of the processing space PS reaches target intermediate pressure between the initial pressure P1 and the first pressure P1 and, for example, the target intermediate pressure may be about 75 bar to about 90 bar. Due to such a sharp change in pressure, turbulence may be generated in the processing space PS. In some example embodiments, when the pressure of the processing space PS reaches the target intermediate pressure through the first supply operation, the second supply operation may be performed. The second supply operation may be performed such that the pressure of the processing space PS reaches the first pressure P1.

In third operation S130, the material (for example, a cleaning solution or a rinse solution) on the substrate WF may be mixed (or substituted) with the processing fluid PF and a mixed fluid may be discharged through the exhaust tube 160. Third operation S130 may include a pressure-reducing process of reducing the pressure of the processing space PS from the first pressure P1 to second pressure P2, which is lower than the first pressure P1, and a pressure-increasing process of increasing the pressure of the processing space PS from the second pressure P2 to the first pressure P1. The second pressure P2 may be about 75 bar to about 90 bar.

In some example embodiments, third operation S130 may include repeating the pressure-reducing process and the pressure-increasing process alternately two or more times. The pressure-reducing process may include a process of discharging the discard fluid DF in the processing space PS through the exhaust device 170. The pressure-increasing process may include a process of supplying the processing fluid PF having the second temperature to an upper portion of the processing space PS through the second supply tube 150.

In fourth operation S140, the exhaust device 170 may discharge the discard fluid DF in the processing space PS and thus reduce the pressure of the processing space PS to the initial pressure P0.

In some example embodiments, when the drying process on the substrate WF is completed, the process chamber 110 may switch from the closed position to the open position and fifth operation S150 of unloading the substrate WF from the processing space PS may be performed.

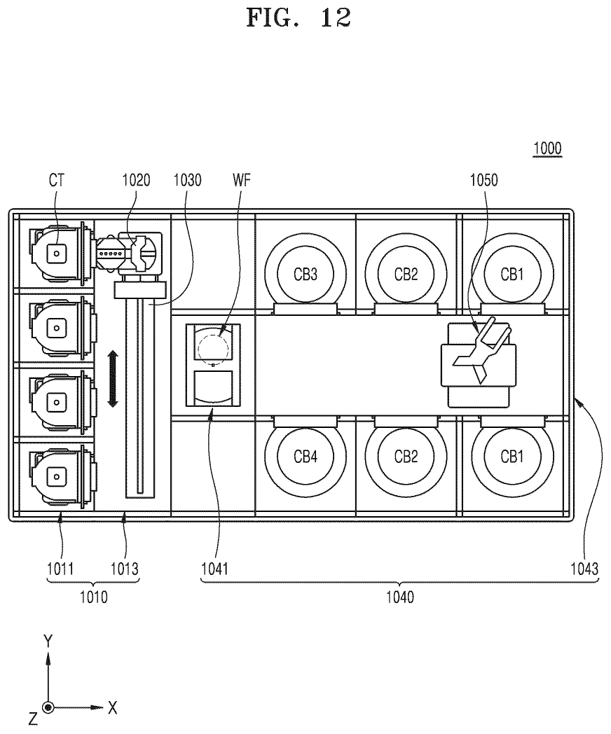

FIG. 12 is a plan view illustrating an overall configuration of a substrate processing apparatus according to an example embodiment.

Referring to FIG. 12, a substrate processing apparatus 1000 may include an index module 1010, a processing module 1040, and a substrate transport unit 1050 (or substrate transport 1050).

The index module 1010 may include a load port 1011 and a transport frame 1013. The load port 1011, the transport frame 1013, and the processing module 1040 may be arranged in a line. Hereinafter, a direction, in which the load port 1011, the transport frame 1013, and the processing module 1040 are arranged in a line, is defined to be a first horizontal direction (X direction), a direction, which is perpendicular to the first horizontal direction (X direction), is defined to be a second horizontal direction (Y direction), and a direction, which is perpendicular to each of the first horizontal direction (X direction) and the second horizontal direction (Y direction), is defined to be a vertical direction (Z direction).

A container CT, in which the substrate WF is received, is settled on the load port 1011. The load port 1011 may be provided in a plural number, and a plurality of load ports 1011 may be arranged in a line in the second horizontal direction (Y direction). Although FIG. 12 illustrates four load ports 1011, the number of load ports 1011 may increase or decrease depending on (or based on) conditions, such as the process efficiency and/or the installation area of the processing module 1040. The container CT may include a plurality of slots each configured to support the edge of the substrate WF. The plurality of slots may be apart from each other in the vertical direction (Z direction), and thus, a plurality of substrates WF are mounted in the container CT to overlap each other in the vertical direction (Z direction). The container CT may include, for example, a front-opening unified pod (FOUP).

The transport frame 1013 may transport the substrate WF between the container CT on the load port 1011 and a buffer chamber 1041 of the processing module 1040. The transport frame 1013 may include an index robot 1020 and an index rail 1030. The index rail 1030 may extend in the second horizontal direction (Y direction). The index robot 1020 may be mounted on the index rail 1030 and may move straightly in the second horizontal direction (Y direction) along the index rail 1030.

The processing module 1040 may include the buffer chamber 1041, a transport chamber 1043, and first to fourth process chambers CB1, CB2, CB3, and CB4. The transport chamber 1043 extends in the first horizontal direction (X direction). In some example embodiments, the first to fourth process chambers CB1, CB2, CB3, and CB4 may be apart from each other in the second horizontal direction (Y direction) with the transport chamber 1043 therebetween. In some example embodiments, the first to fourth process chambers CB1, CB2, CB3, and CB4 may be arranged in the first horizontal direction (X direction). In some example embodiments, some of the first to fourth process chambers CB1, CB2, CB3, and CB4 may be stacked in the vertical direction (Z direction).

The arrangement of the first to fourth process chambers CB1, CB2, CB3, and CB4 shown in FIG. 12 is only an example, and the first to fourth process chambers CB1, CB2, CB3, and CB4 may be variously arranged as needed. For example, all the first to fourth process chambers CB1, CB2, CB3, and CB4 may be arranged only on one side of the transport chamber 1043 (or may be arranged on one side of the transport chamber 1043).

The buffer chamber 1041 may be arranged between the transport frame 1013 and the transport chamber 1043. The buffer chamber 1041 may provide a space, in which the substrate WF is stored, between transport chamber 1043 and the transport frame 1013. The buffer chamber 1041 may include a plurality of slots each corresponding to an inner space, in which the substrate WF is stored. The plurality of slots may overlap and be apart from each other in the vertical direction (Z direction). The buffer chamber 1041 may include an opening, through which the substrate WF may move in and from the buffer chamber 1041, in each of a surface thereof facing the transport frame 1013 and a surface thereof facing the transport chamber 1043.

The transport chamber 1043 may transport the substrate WF between buffer chamber 1041 and each of the first to fourth process chambers CB1, CB2, CB3, and CB4. A substrate transport unit 1050 may be located in the transport chamber 1043. The substrate transport unit 1050 may be mounted on a rail extending in the first horizontal direction (X direction) and may move straightly in the first horizontal direction (X direction) along the rail. The substrate WF may be transported between the first to fourth process chambers CB1, CB2, CB3, and CB4 by the substrate transport unit 1050.

The first to fourth process chambers CB1, CB2, CB3, and CB4 may respectively and sequentially perform processes on one substrate WF. For example, an etching process may be performed on the substrate WF in the first process chamber CB1, and then, a drying process may be performed on the substrate WF in the second process chamber CB2. The etching process is a process of removing a portion of a film to be etched, by using, as an etch mask, a portion of a photoresist having been exposed (or not having been exposed) to EUV light during an exposure process. The drying process may be performed by a processing fluid in a supercritical state. In some example embodiments, the processing fluid in a supercritical state may include carbon dioxide (CO₂).

The first process chamber CB1 may provide a process solution (for example, a cleaning solution or a rinse solution) to the substrate WF in a dry state by using an ejection device. For example, the substrate WF in a dry state may become the substrate WF in a wet state due to the process solution in the first process chamber CB1. The first process chamber CB1 may be arranged in a plural number in the processing module 1040, and the number of first process chambers CB1 may increase or decrease depending on (or based on) conditions, such as the process efficiency and/or the installation area of the processing module 1040.

The second process chamber CB2 may receive the substrate WF in a wet state from the first process chamber CB1 and may remove the process solution from the received substrate WF by using a supercritical fluid for the received substrate WF. According to the related art, although a method of rotating the substrate WF at high speed has been used, fine patterns may collapse due to surface tension upon during the high-speed rotation. To solve this issue, a process solution may be dissolved in a supercritical fluid, followed by discharging the supercritical fluid, thereby removing the process solution. In some example embodiments, by removing the process solution and the supercritical fluid together from the substrate WF, the substrate WF in a wet state may be dried. For example, due to the drying process in the second process chamber CB2, the substrate WF in a wet state may become the substrate WF in a dry state. The second process chamber CB2 may be arranged in a plural number in the processing module 1040, and the number of second process chambers CB2 may increase or decrease depending on (or based on) conditions, such as the process efficiency and/or the installation area of the processing module 1040. In some example embodiments, the second process chamber CB2 may include one of the substrate processing apparatuses 10, 20, 30, and 40 described above.

The third process chamber CB3 may receive the substrate WF from the second process chamber CB2 and may perform a bake process to completely dry the substrate WF (or to dry the substrate WF). The bake process may be performed on the substrate WF at a temperature of about 120° C. to about 170° C. for about 30 seconds to about 120 seconds by a hot plate in the third process chamber CB3. For example, due to the bake process in the third process chamber CB3, the substrate WF may be maintained in a dry state.

The fourth process chamber CB4 may receive the substrate WF from the third process chamber CB3 and may perform a cooling process to reduce the temperature of the substrate WF. The cooling process may be performed by a cooling plate in the fourth process chamber CB4. For example, due to the cooling process in the fourth process chamber CB4, the substrate WF may be maintained in a dry state.

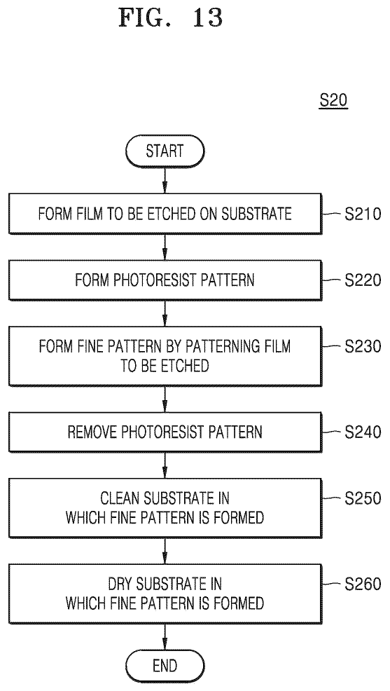

FIG. 13 is a flowchart illustrating a method of forming a fine pattern by using a substrate processing apparatus according to an example embodiment.

Referring to FIG. 13, the method S20 of forming a fine pattern may include a process sequence of first to sixth operations S210 to S260.

In some example embodiments, when a certain example embodiment is able to be implemented otherwise, a particular process sequence may be performed differently from a described sequence. For example, two processes consecutively described may be performed substantially at the same time or may be performed in a reverse sequence to a described sequence.

The method S20 of forming a fine pattern, according to the inventive concepts, includes first operation S210 of forming a film to be etched on a substrate, second operation S220 of forming a photoresist pattern, third operation S230 of forming a fine pattern by patterning the film to be etched, fourth operation S240 of removing the photoresist pattern, fifth operation S250 of cleaning the substrate in which the fine pattern is formed, and sixth operation S260 of drying the substrate in which the fine pattern is formed.

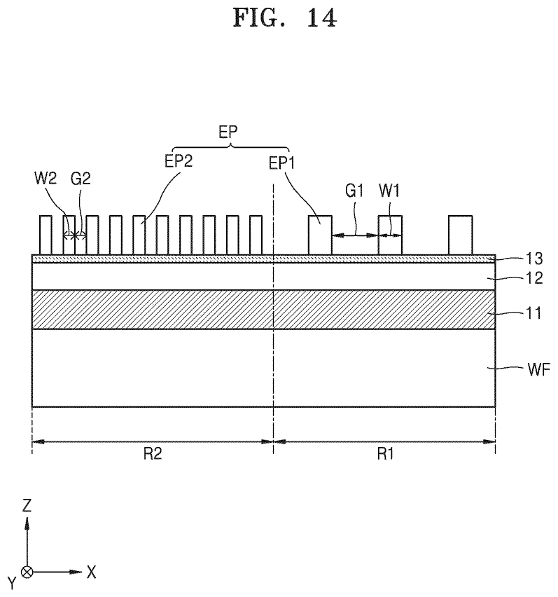

Technical features regarding each of first to sixth operations S210 to S260 are described below in detail with reference to FIGS. 14 to 16.

FIGS. 14 to 16 are cross-sectional views respectively illustrating a sequence of processes of the method of forming a fine pattern in FIG. 13.

Referring to FIG. 14, an etching-target film 11 may be formed on the substrate WF, followed by forming first and second mask layers 12 and 13 on the etching-target film 11, and then, an EUV photoresist pattern EP may be formed on the second mask layer 13.

The substrate WF, which includes a semiconductor material, may include a Group IV semiconductor or a Group III-V compound semiconductor. For example, the Group IV semiconductor may include silicon (Si), germanium (Ge), or silicon-germanium (SiGe). The substrate WF may be provided as a bulk wafer or as a wafer including an epitaxial layer. Although not shown, for example, unit elements, such as various active or passive elements, required to form a semiconductor device may have been formed in the substrate WF. The substrate WF may be divided into a first region RI and a second region R2.

The etching-target film 11 may be arranged on the substrate WF. The etching-target film 11 may include a single film or a multilayered film in which a plurality of material films are stacked. The etching-target film 11 may include a material film having etch selectivity with respect to the first and second mask layers 12 and 13. For example, the etching-target film 11 may include, but is not limited to, polysilicon.

Each of the first and second mask layers 12 and 13 may include various material layers for forming a target pattern on the etching-target film 11. The first mask layer 12 may be formed on the etching-target film 11, and the second mask layer 13 may be formed on the first mask layer 12.

In some example embodiments, each of the first and second mask layers 12 and 13 may have various thicknesses to form the target pattern on the etching-target film 11. For example, the thickness of the second mask layer 13 may be less than the thickness of the first mask layer 12.

The EUV photoresist pattern EP may be formed on the second mask layer 13. The EUV photoresist pattern EP may be formed through the formation, light-exposure, and development of a photoresist film, which reacts to EUV light, by using an EUV exposure apparatus (not shown).

The EUV photoresist pattern EP may include a plurality of line patterns (e.g., EPI and EP2) depending on (or based on) formation positions thereof. Here, for convenience of description, patterns formed in the first region R1, from among the plurality of line patterns (e.g., EP1 and EP2), are referred to as a plurality of first patterns EP1, and patterns formed in the second region R2, from among the plurality of line patterns (e.g., EPI and EP2), are referred to as a plurality of second patterns EP2.

The plurality of first patterns EPI may include first line-and-space patterns in which mask lines having the same first width WI are apart from each other with the same first gap G1 in the first horizontal direction (X direction) and extend parallel to each other in the second horizontal direction (Y direction). In some example embodiments, the plurality of second patterns EP2 may include second line-and-space patterns in which mask lines having the same second width W2 are apart from each other with the same second gap G2 in the first horizontal direction (X direction) and extend parallel to each other in the second horizontal direction (Y direction).

In some example embodiments, the first gap G1 of the plurality of first patterns EPI may be greater than the second gap G2 of the plurality of second patterns EP2. In some example embodiments, the first width WI of the plurality of first patterns EPI may be greater than the second width W2 of the plurality of second patterns EP2. However, this is only an example for convenience of description, and the inventive concepts are not limited thereto.

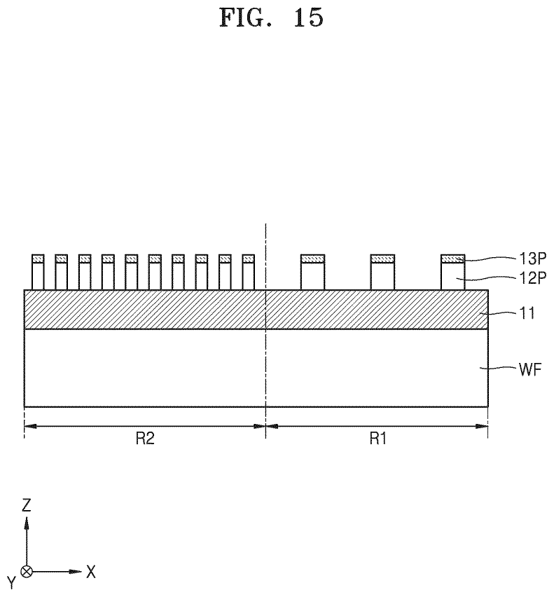

Referring to FIG. 15, the second and first mask layers 13 and 12, which are under the EUV photoresist pattern EP, may be sequentially etched in the stated order by using the EUV photoresist pattern EP (e.g., see FIG. 14), which is dried, as an etch mask.

The first and second mask layers 12 and 13 (e.g., see FIG. 14) may be anisotropically etched by using the EUV photoresist pattern EP (e.g., see FIG. 14), which is dried, as an etch mask, thereby forming first and second mask patterns 12P and 13P. For example, as an anisotropic etching method for forming the first and second mask patterns 12P and 13P, a dry etching process, such as reactive ion etching (RIE) or inductively coupled plasma (ICP) etching, may be used.

Next, the dried EUV photoresist pattern EP (e.g., see FIG. 14) may be removed. The dried EUV photoresist pattern EP (e.g., see FIG. 14) may be removed by ashing and strip processes. The process of removing the dried EUV photoresist pattern EP (e.g., see FIG. 14) may be performed under the condition of suppressing the first and second mask patterns 12P and 13P from being etched.

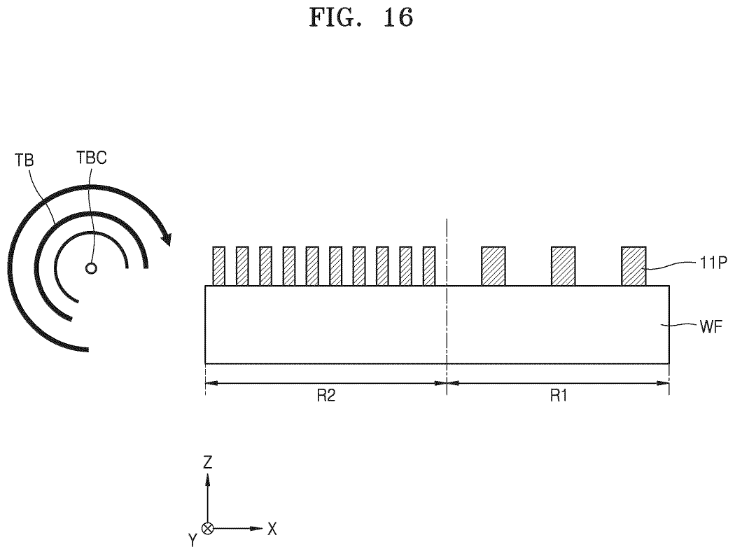

Referring to FIG. 16, the etching-target film 11 (e.g., see FIG. 15), which is under the first and second mask patterns 12P and 13P (e.g., see FIG. 15), may be etched by using the first and second mask patterns 12P and 13P as an etch mask, thereby forming a target pattern 11P on the substrate WF.

The etching-target film 11 (e.g., see FIG. 15) may be anisotropically etched by using the first and second mask patterns 12P and 13P (e.g., see FIG. 15) as an etch mask, thereby forming the target pattern 11P. As an anisotropic etching method for forming the target pattern 11P, a dry etching process, such as RIE or ICP etching, may be used. The target pattern 11P may include, but is not limited to, a fine pattern having a high aspect ratio, for example, an STI pattern. In some example embodiments, the high aspect ratio refers to, but is not limited to, a width-to-height ratio of about 1:5 to about 1:100.

Next, all the first and second mask patterns 12P and 13P (e.g., see FIG. 15), which are on or over the target pattern 11P, may be removed. The removal process may be performed under the condition of suppressing the target pattern 11P from being etched.

A drying process may be performed on the substrate WF in which the target pattern 11P is formed as such. Referring to FIG. 1 together with FIGS. 14 to 16, the substrate processing apparatus 10 according to the inventive concepts may allow the center TBC of the turbulence TB to be formed outwards apart from the edge of the substrate WF by using the substrate support 120 including the turbulence reduction wing unit 125, which is tilted at the first angle D1 toward the lower surface 111 of the process chamber 110 (e.g., in the −Z direction), thereby efficiently preventing (or reducing) a leaning phenomenon of the target pattern 11P in the second region R2 of the substrate WF and improving the uniformity of the drying process of the substrate WF.

While the inventive concepts have been particularly shown and described with reference to embodiments thereof, it will be understood that various changes in form and details may be made therein without departing from the spirit and scope of the following claims.

What is claimed is:

1. A substrate processing apparatus comprising:
a process chamber including a processing space;
a substrate support configured to support a substrate in the process chamber;
a fluid supply tube arranged in a lower portion of the process chamber; and
a fluid supply device configured to supply a supercritical fluid to the processing space through the fluid supply tube,
wherein the substrate support includes
a plate structure that is arranged in a central region of the substrate support, and on which the substrate is settled;
a turbulence reduction body having a ring shape and joined to an outer portion of the plate structure; and
a turbulence reduction wing joined to an outer portion of the turbulence reduction body and tilted at an angle toward the lower portion of the process chamber.

2. The substrate processing apparatus of claim 1, wherein the angle between an upper surface of the plate structure and an upper surface of the turbulence reduction wing is greater than about 0 degrees) (°) and less than about 90°.

3. The substrate processing apparatus of claim 2, wherein the angle between the upper surface of the plate structure and the upper surface of the turbulence reduction wing is about 20°.

4. The substrate processing apparatus of claim 1, wherein a diameter of the plate structure is less than a diameter of the substrate, and
wherein a diameter of the turbulence reduction body is equal to or greater than the diameter of the substrate.

5. The substrate processing apparatus of claim 4, wherein a total diameter of the plate structure and the turbulence reduction body is determined from a range of about 300 mm to about 335 mm.

6. The substrate processing apparatus of claim 1, wherein the plate structure comprises a lower structure having a first diameter and an upper structure having a second diameter that is greater than the first diameter of the lower structure, and
wherein a thickness of the turbulence reduction body is less than a thickness of the upper structure.

7. The substrate processing apparatus of claim 6, wherein an upper surface of the upper structure of the plate structure, an upper surface of the turbulence reduction body, and an uppermost surface of the turbulence reduction wing are at an equal level.

8. The substrate processing apparatus of claim 7, wherein the upper surface of the turbulence reduction wing has a decreasing level away from the turbulence reduction body, and
wherein the turbulence reduction wing has a decreasing thickness away from the turbulence reduction body.

9. The substrate processing apparatus of claim 1, wherein the supercritical fluid is introduced from under the plate structure, passes along the turbulence reduction body and the turbulence reduction wing, and then flows into the processing space.

10. The substrate processing apparatus of claim 9, wherein, in the processing space, a center of turbulence generated due to an inflow of the supercritical fluid at high pressure is formed outwards apart from an edge of the substrate.

11. A substrate processing apparatus comprising:
a process chamber including a processing space;
a substrate support configured to support a substrate in the process chamber;
a fluid supply tube arranged in a side portion of the process chamber; and
a fluid supply device configured to supply a supercritical fluid to the processing space through the fluid supply tube,
wherein the substrate support includes
a plate structure that is arranged in a central region of the substrate support, and on which the substrate is settled;
a turbulence reduction body having a ring shape and joined to an outer portion of the plate structure; and
a turbulence reduction wing joined to an outer portion of the turbulence reduction body and tilted at an angle toward an upper portion of the process chamber.

12. The substrate processing apparatus of claim 11, wherein the angle between an upper surface of the plate structure and an upper surface of the turbulence reduction wing is greater than about 0 degrees) (°) and less than about 90°.

13. The substrate processing apparatus of claim 11, wherein a diameter of the plate structure is less than the diameter of the substrate, and
wherein the diameter of the turbulence reduction body is equal to or greater than the diameter of the substrate.

14. The substrate processing apparatus of claim 11, wherein an upper surface of the turbulence reduction wing has an increasing level away from the turbulence reduction body, and
wherein the turbulence reduction wing has a decreasing thickness away from the turbulence reduction body.

15. The substrate processing apparatus of claim 11, wherein the supercritical fluid is introduced from the side portion of the process chamber into the processing space toward the turbulence reduction wing.

16. A substrate processing apparatus comprising:
a substrate support including
a plate structure, on which a substrate is settled;
a turbulence reduction body having a ring shape and joined to an outer portion of the plate structure; and
a turbulence reduction wing joined to an outer portion of the turbulence reduction body and having an upper surface that is tilted,
wherein the substrate processing apparatus is configured to dry a substrate by using a supercritical fluid, and
wherein a center of turbulence generated due to an inflow of the supercritical fluid at high pressure is formed outwards apart from an edge of the substrate by using the substrate support.

17. The substrate processing apparatus of claim 16, wherein the substrate comprises a fine pattern having a high aspect ratio.

18. The substrate processing apparatus of claim 17, wherein, because the center of the turbulence and the edge of the substrate are apart from each other in a horizontal direction, a leaning phenomenon of the fine pattern having a high aspect ratio on the substrate is prevented.

19. The substrate processing apparatus of claim 16, wherein the turbulence reduction wing comprises:
a parallel portion having an upper surface that is parallel to an upper surface of the turbulence reduction body; and
a tilted portion having an upper surface that is tilted,
wherein the supercritical fluid is introduced from a lower portion of the substrate processing apparatus, and
wherein the tilted upper surface of the tilted portion has a descending slope facing downwards.

20. The substrate processing apparatus of claim 16, wherein the turbulence reduction wing comprises:
a parallel portion having an upper surface that is parallel to an upper surface of the turbulence reduction body; and
a tilted portion having an upper surface that is tilted.
wherein the supercritical fluid is introduced from a side portion of the substrate processing apparatus, and
wherein the tilted upper surface of the tilted portion has an ascending slope facing upwards.
